(19) United States
(12) Patent Application Publication
(10) Pub. No.: US 2012/0185741 A1
(43) Pub. Date: Jul. 19, 2012

(54) APPARATUS AND METHOD FOR DETECTING A MEMORY ACCESS ERROR

(76) Inventors: Sergey Sergeevich Grekhov, Stupino (RU); Alexey Anatolevich Gerenkov, Dedovsk (RU); Ekaterina Anatolevna Gorelkina, Moscow (RU)

(21) Appl. No.: 13/181,844

(22) Filed: Jul. 13, 2011

(30) Foreign Application Priority Data
Jan. 14, 2011 (RU) RU2011101098
Apr. 6, 2011 (KR) 10-2011-0031851

(51) Int. Cl. G11C 29/04; G06F 11/22

(52) U.S. Cl. 714/719; 714/E11.145

(57) ABSTRACT

Provided are an apparatus and method for detecting a memory access error in a computer system. The apparatus and method may intercept a sub-system that processes a request for access to a memory, and may be applied to various computer systems without causing any performance deterioration. The apparatus includes a sub-system configured to process a request for access to a memory, and an interception module configured to detect a memory access address by intercepting the sub-system.

### CROSS-REFERENCE TO RELATED APPLICATION(S)

This application claims the benefit under 35 U.S.C. §119(a) of Russian Patent Application No. RU2011101098, filed on Jan. 14, 2011, in the Russian Patent and Trademark Office, and claims the benefit under 35 U.S.C. §119(a) of Korean Patent Application No. 10-2011-0031851, filed on Apr. 6, 2011, in the Korean Intellectual Property Office, the entire disclosures of which are incorporated herein by reference for all purposes.

### BACKGROUND

1. Field

The following description relates to a memory access error detection technique that may be implemented in various computer systems.

2. Description of the Related Art

Software programs that are used in current computer systems typically have complicated debugging processes that take up a considerable amount of time to perform debugging. To simplify debugging, various debugging software programs such as debugging tools for detecting memory access errors have been developed. Debugging software programs are highly dependent on the type of computer systems. Due to relatively complicated porting processes, debugging software programs can be difficult to apply to a variety of computer systems.

Therefore, a technique is needed that allows debugging software to be applied to various types of computer systems.

### SUMMARY

In one general aspect, there is provided an apparatus for detecting a memory access error in a computer, the apparatus including a sub-system configured to process a request for access to memory, a detection unit configured to detect a memory access address by intercepting the sub-system, and an error determination unit configured to determine whether a memory access error has occurred by comparing the memory access address with addresses in a first memory region that is an additional memory region, addresses in a second memory region that is a memory region to which objects are allocated, and addresses in a third memory region that is a memory region to which no objects are allocated.

The apparatus may further comprise an allocation unit configured to intercept a memory allocation request signal and allocate the first and second memory regions to a memory each time a memory allocation request signal is intercepted.

The apparatus may further comprise a setting unit configured to block access to the first and second memory regions.

The error determination unit may be further configured to determine that a memory access error has occurred, in response to the memory access address belonging to the first memory region or the third memory region.

The error determination unit may be further configured to determine that no memory access error has occurred, in response to the memory access address belonging to the second memory region.

The apparatus may further comprise a setting unit configured to unblock access to the first and second memory regions.

A size of the first memory region may be determined based on a size of pages in the memory, a size of the second memory region, and a main size that is determined based on the size of pages in the memory.

In another aspect, there is provided a method of detecting a memory access error in a computer, the method including detecting a memory access address by intercepting a sub-system that processes a request for access to a memory, and determining whether a memory access error has occurred by comparing the memory access address with addresses in a first memory region that is an additional memory region, addresses in a second memory region that is a memory region to which objects are allocated, and addresses in a third memory region that is a memory region to which no objects are allocated.

The method may further comprise intercepting a memory allocation request signal, and allocating the first and second memory regions to memory each time a memory allocation request signal is intercepted.

The method may further comprise blocking access to the first and second memory regions.

The determining may comprise determining that a memory access error has occurred, in response to the memory access address belonging to the first memory region or the third memory region.

The determining may comprise determining that no memory access error has occurred, in response to the memory access address belonging to the second memory region.

The method may further comprise unblocking access to the first and second memory regions.

A size of the first memory region may be determined based on a size of pages in the memory, a size of the second memory region, and a main size that is determined based on the size of pages in the memory.

In another aspect, there is provided a terminal comprising a sub-system for processing a request for access to a memory, the terminal including an interception module configured to intercept a memory address included in a memory allocation request signal that is sent to the sub-system, and a determination unit configured to determine a memory access error by comparing the memory address with addresses stored in the memory, and in response to determining that a memory access error has occurred, the determination unit is configured to block access to the memory.

The interception module may be further configured to intercept a memory allocation request signal or memory deallocation request signal that is input to an interface of the memory, and configured to allocate a first memory region to detect an overflow and a second memory region to which objects are allocated, each time a memory allocation request signal or memory deallocation request signal is intercepted at the interface of the memory.

The interception module may be configured to block access to the first and second memory regions.

The determination unit may be configured to compare the memory address to addresses included in the first and second memory regions.

In response to the determination unit determining that the memory address belongs to the first memory region or to another inaccessible memory region, the interception module may be configured to continue to block access to the first and second memory regions.

The terminal of claim 18, wherein, in response to the determination unit determining that the memory belongs to the second memory region to which objects are allocated, the interception module may be configured to unblock access to the first and second memory regions.

Other features and aspects may be apparent from the following detailed description, the drawings, and the claims.

### BRIEF DESCRIPTION OF THE DRAWINGS

FIG. 1 is a diagram illustrating an example of an apparatus for detecting a memory access error in a computer.

FIG. 2 is a flowchart illustrating an example of a method for detecting a memory access error in a computer.

FIG. 3 is a diagram illustrating an example of a memory of a computer.

FIG. 4 is a diagram illustrating an example of an interception module illustrated in FIG. 3 that allocates first and second memory regions to a memory.

FIG. 5 is a flowchart illustrating another example of a method for detecting a memory access error in a computer.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

The following description is provided to assist the reader in gaining a comprehensive understanding of the methods, apparatuses, and/or systems described herein. Accordingly, various changes, modifications, and equivalents of the methods, apparatuses, and/or systems described herein may be suggested to those of ordinary skill in the art. Also, descriptions of well-known functions and constructions may be omitted for increased clarity and conciseness.

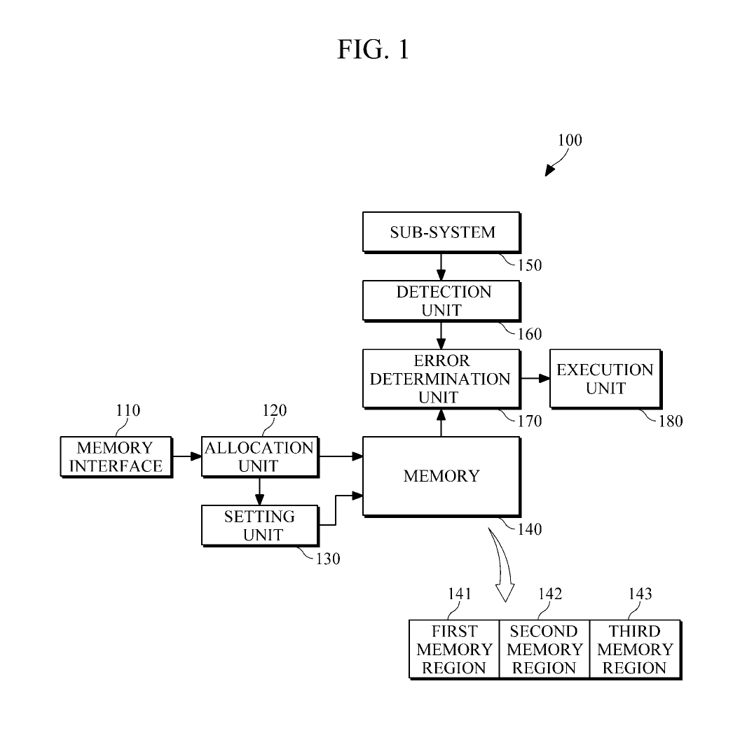

FIG. 1 illustrates an example of an apparatus for detecting a memory access error in a computer. For example, the apparatus may be or may be included in a terminal such as a mobile terminal, a smart phone, a computer, a tablet, a home appliance, a sensor, and the like.

Referring to FIG. 1, apparatus 100 includes a memory interface 110, an allocation unit 120, a setting unit 130, a memory 140, a sub-system 150, a detection unit 160, an error determination unit 170, and an execution unit 180. A module that includes the allocation unit 120, the setting unit 130, the detection unit 160, the error determination unit 170, and the execution unit 180 may be referred to as an interception module.

The memory interface 110 may allocate and/or deallocate objects to the memory 140 based on a memory access signal such as a memory allocation request signal or a memory deallocation request signal. For example, the memory interface 110 may be an application programming interface for memory allocation.

The allocation unit 120 may intercept a memory allocation request signal. For example, the allocation unit 120 may allocate a first memory region 141 and a second memory region 142 to the memory 140 each time the memory allocation request signal is intercepted.

The first memory region 141 may be additionally allocated to detect an overflow error. The first memory region 141 may also be referred to as a red zone. The first memory region 141 may have a size that is large enough to detect an overflow of objects.

The size of the first memory region 141 may be determined based on the size of pages that are stored in memory 140 and based on a main size. The main size may be determined based on the size of the second memory region 142 and the size of pages that are stored in the memory 140. For example, a size of the first memory region 141 may be calculated by Equation (1):

Size of First Memory Region=N*page_size−main_size (1),

where page_size indicates the size of pages in the memory 140, main_size indicates the size of the second memory region 142 that is added to page_size/4, and N is a value that is greater than main_size/page_size and is a value that is the same as or less than page_size/main_size+1 (i.e., main_size/page_size<N≦page_size/main_size+1).

The second memory region 142 may be a memory region to which objects are allocated. For example, the allocation unit 120 may allocate objects to the second memory region 142, in response to the memory allocation request signal being applied.

In response to the first and second memory regions 141 and 142 being allocated to the memory 140, the setting unit 130 may block access to the first and second memory regions 141 and 142. For example, the setting unit 130 may prevent the first or second memory regions 141 and 142 from being written to or from being read from.

The setting unit 130 may determine whether all of the objects that are allocated to the memory 140 are access-blocked. If it is determined that not all of the objects allocated to the memory 140 are access-blocked, the setting unit 130 may detect objects that are not access-blocked, and may block access to the detected objects.

In the example of FIG. 1, the memory 140 includes the first memory region 141, the second memory regions 142, and a third memory region 143. As described herein, the first memory region 141 may be a memory region that is additionally allocated to detect an overflow of objects. The second memory region 142 may be a memory region to which objects are allocated. In this example, the third memory region 143 may be the memory 140 that excludes the first and second memory regions 141 and 142, and may be a memory region to which no objects are allocated.

For example, the memory 140 may correspond to a heap memory region. The heap memory region may be a memory region that is allocated by a programmer. The heap memory region may be generated by dynamic allocation. For example, in response to a memory allocation request being issued during the execution of a program, a portion of the heap memory region may be allocated for the execution of the program.

The sub-system 150 may process a request for access to the memory 140. As an example, the sub-system 150 may be included in an operating system (OS). The detection unit 160 may detect a memory access address by intercepting the sub-system 150. The error determination unit 170 may determine whether a memory access error has occurred by comparing a memory access address that is detected by the detection unit 160 and addresses that are stored in each of the first, second, and third memory regions 141, 142, and 143.

For example, in response to the memory access address detected by the detection unit 160 belonging to each of the first and third memory regions 141 and 143, the error determination unit 170 may determine that a memory access error has occurred.

As an example, in response to the memory access address detected by the detection unit 160 belonging to the first memory region 141, the error determination unit 170 may determine that a memory access error has occurred. In this example, the error determination unit 170 may continue to block access to the first and second memory regions 141 and 142. The error determination unit 170 may generate an error message that indicates the occurrence of the memory access error. The execution unit 180 may resume program execution at a next instruction. To execute the next instruction, the execution unit 180 may increase the counter value of a counter register (not shown) of a processor (not shown).

As another example, in response to the memory access address detected by the detection unit 160 belonging to the third memory region 143, the error determination unit 170 may determine that a memory access error has occurred, and may generate an error message that indicates the occurrence of the memory access error, and the execution unit 180 may resume program execution.

As another example, in response to the memory access address detected by the detection unit 160 belonging to the second memory region 142 to which objects are allocated, the error determination unit 170 may determine that no memory access error has occurred, and the setting unit 130 may unblock access to the first and second memory regions 141 and 142.

The execution unit 180 may resume program execution based on the results of the determination that is performed by the error determination unit 170.

In various aspects, the apparatus 100 may detect a memory access address by intercepting the sub-system 150, and may be applied to various computer systems without causing performance deterioration.

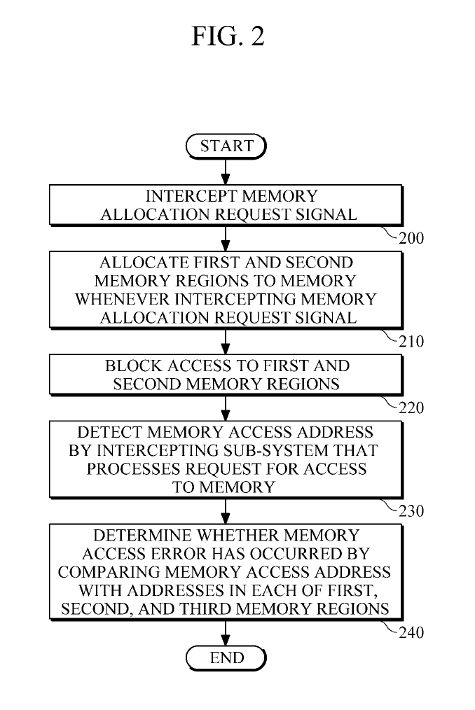

FIG. 2 illustrates an example of a method for detecting a memory access error in a computer.

Referring to FIG. 2, in 200, an apparatus for detecting a memory access error in a computer system intercepts a memory allocation request signal. In 210, the apparatus allocates first and second memory regions to a memory each time the memory allocation request signal is intercepted. In this example, the memory also includes a third memory region to which objects are not allocated at this time. In 220, the apparatus blocks access to the first and second memory regions.

For example, the first memory region may be a memory region that is additionally allocated to detect an error such as an overflow of objects. The size of the first memory region may be determined based on the size of pages stored in the memory and a main size. The main size may be determined based on the size of the second memory region and the size of pages stored in the memory. The second memory region may be a memory region to which objects are allocated.

In 230, the apparatus detects a memory access address by intercepting a sub-system that processes a request for access to the memory. In 240, the apparatus determines whether a memory access error has occurred by comparing the detected memory access address to the addresses stored in the first, second, and third memory regions.

For example, in response to the detected memory access address detected belonging to the first memory region, the apparatus may determine that a memory access error has occurred. In this example, the apparatus may continue to block access to the first and second memory regions, may generate an error message that indicates the occurrence of the memory access error, and may resume program execution at a next instruction. To execute the next instruction, the apparatus may increase the counter value of a counter register of a processor.

As another example, in response to the detected memory access address belonging to the third memory region, the apparatus may determine that a memory access error has occurred, and may generate an error message that indicates the occurrence of the memory access error, and the execution unit 180 may resume program execution.

As another example, in response to the detected memory access address belonging to the second memory region to which objects are allocated, the apparatus may determine that no memory access error has occurred, and the setting unit 130 may unblock access to the first and second memory regions.

According to the example illustrated in FIG. 2, it is possible to detect a memory access address by intercepting a sub-system. The example illustrated in FIG. 2 may be applied to various computer systems without causing performance deterioration.

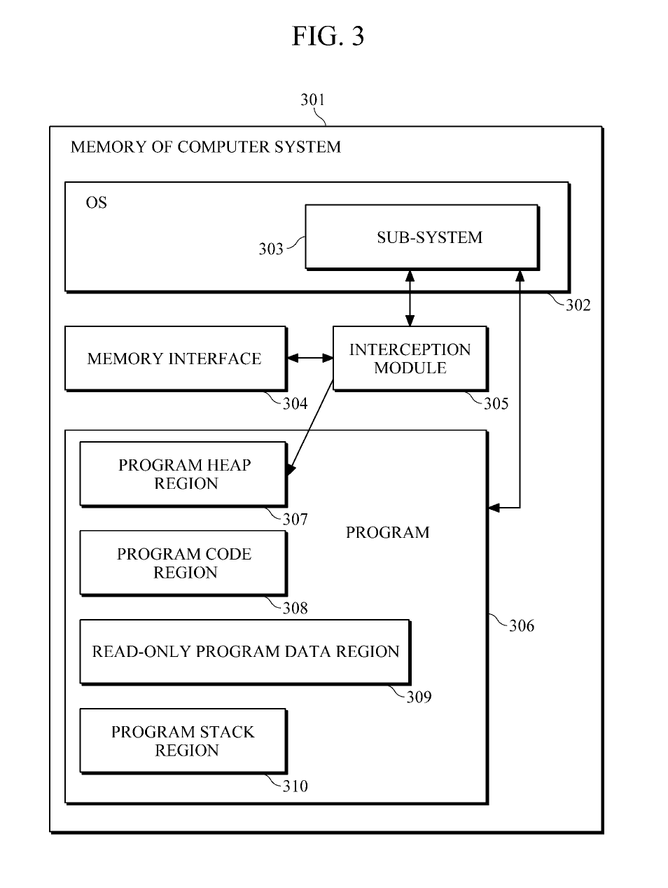

FIG. 3 illustrates an example of a memory of a computer.

Referring to FIG. 3, memory 301 includes an OS 302, a memory interface 304, an interception module 305, and a program 306.

In this example, the OS 302 includes a sub-system 303. The sub-system 303 may process a request for access to the memory 301.

The memory interface 304 may be an interface that is used for allocating and/or deallocating objects to the memory 301.

The interception module 305 may intercept a memory allocation request signal and/or a memory deallocation request signal that are input to the memory interface 304. For example, the interception module 305 may generate an additional memory region (i.e., a first memory region) in a program heap region 307 each time the memory allocation request signal is intercepted. The first memory region may also be referred to as a red zone. The interception module 305 may block access to the first memory region and a second memory region to which objects are allocated, by preventing the first and second memory regions from being written or read. A third memory region is a memory region to which no objects are allocated.

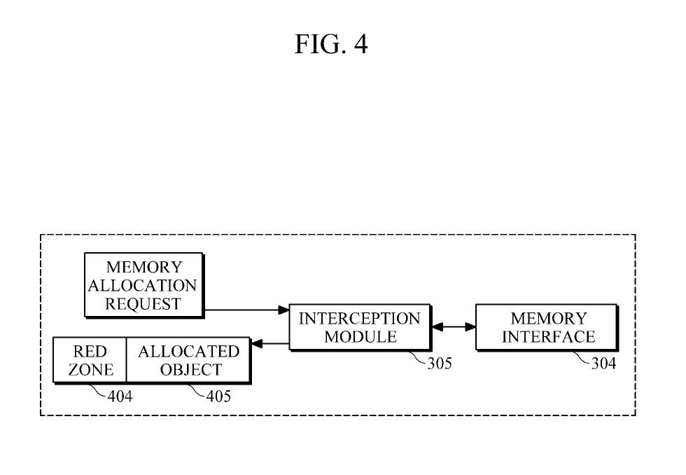

The interception module 305 may intercept the sub-system 303. The sub-system 303 may process a request for access to the memory 301. The interception module 305 may detect any overflow error such as an overflow of objects, based on information that is intercepted from the sub-system 303, and may unblock access to objects, for example, objects that are write-protected or read-protected. An example of the operation of the interception module 305 is described with reference to FIG. 4.

In this example, the program 306 includes the program heap region 307, a program code region 308, a read-only program data region 309, and a program stack region 310.

The program heap region 307 may be a memory region that is allocated by a programmer. The program heap region 307 may be generated by dynamic allocation. For example, in response to a memory allocation request being issued during the execution of the program 306, a portion of the program heap region 307 may be allocated for the execution of the program 306.

The program code region 308 may be a memory region that stores code. For example, the program code region 308 may be a region of memory region that stores instructions of an application program.

The read-only program data region 309 may store data that is available only for reading.

For example, the read-only program data region 309 may store global variables, static variables, and other data arrays and structures and the like.

The stack region 310 may store local variables and parameters that are generated in response to a function being called. The variables allocated to the stack region 310 may disappear when a function terminates. For example, the stack region 310 may store automatic variables and/or return addresses.

An example of a method of detecting a memory access error in a computer system is described.

1. An apparatus for detecting a memory access error in a computer system (hereinafter apparatus) may execute a program that intercepts a memory allocation request signal.

2. Each time the memory allocation request signal is intercepted, the apparatus may generate a data structure. An example of the data structure is further described.
a. A first memory region (or a red zone) that is write-protected and/or read-protected and has a predefined size may be allocated to a memory. The first memory region may have a size that is large enough to detect an overflow of objects.
b. A second memory region that is also write-protected and/or read-protected and has a requested size may be allocated to the memory.

3. A sub-system that controls access to the memory may be included in an OS. The apparatus may detect a memory access error by intercepting information corresponding to a memory access address using an access function of the sub-system as follows.
a. In response to the memory access address belonging to the second memory region, the apparatus may unblock access to the first and second memory regions, may block access to previously accessed memory regions, and may resume program execution.
b. In response to the memory access address belonging to the first memory region, the apparatus may continue to block access to the first and second memory regions, may generate an error message that indicates the occurrence of a memory access error, and may resume program execution at a next instruction by increasing the counter value of a counter register of a processor.
c. In response to the memory access address belonging to a third memory region to which no objects are allocated, the apparatus may generate an error message that indicates that a request for access to the third memory region has been issued, and may resume program execution.

Another example of a method of detecting a memory access error in a computer system is described.

1. An apparatus for detecting a memory access error in a computer system may execute a program that intercepts a memory allocation request signal.

2. Each time the memory allocation request signal is intercepted, the apparatus may generate a data structure. The data structure is further described.
a. A first memory region (or a red zone) that is write-protected and/or read-protected and has a predefined size may be allocated to a memory. For example, the size of the first memory region may be calculated using Equation (1).
b. A second memory region that is also write-protected and/or read-protected and that has a requested size may be allocated to the memory.

3. A sub-system that controls access to the memory may be included in an OS. The apparatus may detect a memory access error by intercepting information corresponding to a memory access address using an access function of the sub-system as follows.
a. The apparatus may determine whether all of the objects are write-protected and read-protected. The objects may be included in their respective memory regions that are allocated through the interception of a memory interface.
b. In response to all of the objects not being write-protected and read-protected, the apparatus may detect objects that are not write-protected and read-protected, and may write-protect and/or read-protect the detected objects.
c. In response to all of the objects being write-protected and read-protected and the memory access address belonging to the second memory region, the apparatus may unblock access to all the objects, and may resume program execution.
d. In response to the memory access address belonging to the first memory region, the apparatus may continue to block access to the first memory region, may generate an error message that indicates the occurrence of a memory access error, and may resume program execution at a next instruction by increasing the counter value of a counter register of a processor.
e. In response to the memory access address belonging to another memory region and the memory region in which the memory access address belongs being accessible, the apparatus may resume program execution.
f. In response to the memory region in which the memory access address belongs not being either the first or second memory region and not being accessible, the apparatus may generate an error message that indicates the occurrence of a memory access error.

As described herein, it is possible to obtain a memory access address easily and quickly using a sub-system that processes a request for access to a memory.

FIG. 4 illustrates an example of an interception module that allocates first and second memory regions to a memory.

Referring to FIGS. 3 and 4, interception module 305 may intercept a memory allocation request signal from the memory interface 304, and may allocate a second memory region 405 to which objects are to be allocated and also a first memory region 404 according to the intercepted memory allocation request signal. The first memory region 404 may also be referred to as a red zone. In this example, the interception module 305 may write-protect and/or read-protect the first and second memory regions 404 and 405. For example, the first memory region 404 may be allocated at the front of the second memory region 405.

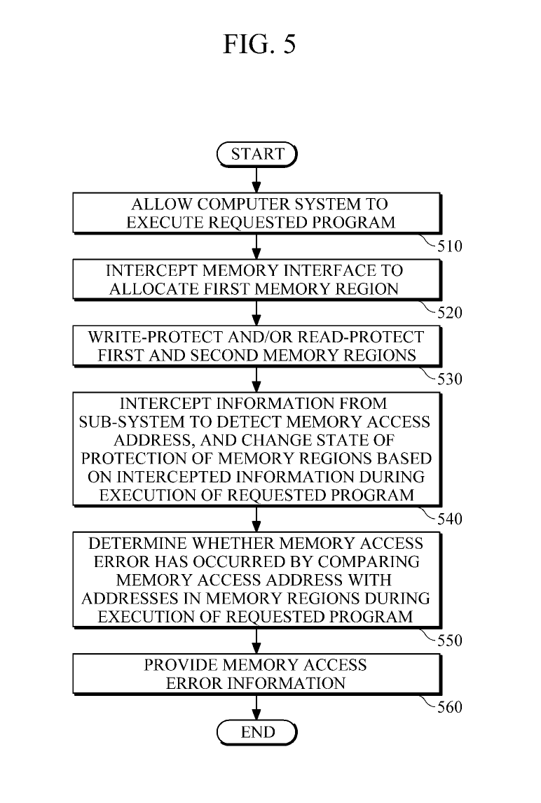

FIG. 5 illustrates another example of a method for detecting a memory access error in a computer.

Referring to FIG. 5, in 510, a computer system executes a requested program. In 520, to allocate a first memory region (i.e., a red zone) that is an additional memory region, an apparatus intercepts a memory interface. In 530, the apparatus write-protects and/or read-protects the first memory region and a second memory region to which objects are to be allocated. In 540, the apparatus intercepts information from a sub-system to detect a memory access address, and changes the state of the protection of a memory region based on the intercepted information.

In 550, the apparatus may determine which of the first memory region, the second memory region, and a third memory region to which no objects are allocated has been accessed, by comparing the memory access address with the addresses in each of the first, second, and third memory regions. In 560, the apparatus provides memory access error information based on the results of the determination performed in 550.

Program instructions to perform a method described herein, or one or more operations thereof, may be recorded, stored, or fixed in one or more computer-readable storage media. The program instructions may be implemented by a computer. For example, the computer may cause a processor to execute the program instructions. The media may include, alone or in combination with the program instructions, data files, data structures, and the like. Examples of computer-readable storage media include magnetic media, such as hard disks, floppy disks, and magnetic tape; optical media such as CD ROM disks and DVDs; magneto-optical media, such as optical disks; and hardware devices that are specially configured to store and perform program instructions, such as read-only memory (ROM), random access memory (RAM), flash memory, and the like. Examples of program instructions include machine code, such as produced by a compiler, and files containing higher level code that may be executed by the computer using an interpreter. The program instructions, that is, software, may be distributed over network coupled computer systems so that the software is stored and executed in a distributed fashion. For example, the software and data may be stored by one or more computer readable storage mediums. Also, functional programs, codes, and code segments for accomplishing the example embodiments disclosed herein can be easily construed by programmers skilled in the art to which the embodiments pertain based on and using the flow diagrams and block diagrams of the figures and their corresponding descriptions as provided herein. Also, the described unit to perform an operation or a method may be hardware, software, or some combination of hardware and software. For example, the unit may be a software package running on a computer or the computer on which that software is running.

As a non-exhaustive illustration only, a terminal/device/unit described herein may refer to mobile devices such as a cellular phone, a personal digital assistant (PDA), a digital camera, a portable game console, and an MP3 player, a portable/personal multimedia player (PMP), a handheld e-book, a portable lab-top PC, a global positioning system (GPS) navigation, and devices such as a desktop PC, a high definition television (HDTV), an optical disc player, a setup box, and the like capable of wireless communication or network communication consistent with that disclosed herein.

A computing system or a computer may include a microprocessor that is electrically connected with a bus, a user interface, and a memory controller. It may further include a flash memory device. The flash memory device may store N-bit data via the memory controller. The N-bit data is processed or will be processed by the microprocessor and N may be 1 or an integer greater than 1. Where the computing system or computer is a mobile apparatus, a is battery may be additionally provided to supply operation voltage of the computing system or computer. It will be apparent to those of ordinary skill in the art that the computing system or computer may further include an application chipset, a camera image processor (CIS), a mobile Dynamic Random Access Memory (DRAM), and the like. The memory controller and the flash memory device may constitute a solid state drive/disk (SSD) that uses a non-volatile memory to store data.

A number of examples have been described above. Nevertheless, it should be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. An apparatus for detecting a memory access error in a computer, the apparatus comprising:
a sub-system configured to process a request for access to memory;
a detection unit configured to detect a memory access address by intercepting the sub-system; and
an error determination unit configured to determine whether a memory access error has occurred by comparing the memory access address with addresses in a first memory region that is an additional memory region, addresses in a second memory region that is a memory region to which objects are allocated, and addresses in a third memory region that is a memory region to which no objects are allocated.

2. The apparatus of claim 1, further comprising an allocation unit configured to intercept a memory allocation request signal and allocate the first and second memory regions to a memory each time a memory allocation request signal is intercepted.

3. The apparatus of claim 2, further comprising a setting unit configured to block access to the first and second memory regions.

4. The apparatus of claim 1, wherein the error determination unit is further configured to determine that a memory access error has occurred, in response to the memory access address belonging to the first memory region or the third memory region.

5. The apparatus of claim 1, wherein the error determination unit is further configured to determine that no memory access error has occurred, in response to the memory access address belonging to the second memory region.

6. The apparatus of claim 5, further comprising a setting unit configured to unblock access to the first and second memory regions.

7. The apparatus of claim 1, wherein a size of the first memory region is determined based on a size of pages in the memory, a size of the second memory region, and a main size that is determined based on the size of pages in the memory.

8. A method of detecting a memory access error in a computer, the method comprising:
detecting a memory access address by intercepting a sub-system that processes a request for access to a memory; and
determining whether a memory access error has occurred by comparing the memory access address with addresses in a first memory region that is an additional memory region, addresses in a second memory region that is a memory region to which objects are allocated, and addresses in a third memory region that is a memory region to which no objects are allocated.

9. The method of claim 8, further comprising:
intercepting a memory allocation request signal; and
allocating the first and second memory regions to memory each time a memory allocation request signal is intercepted.

10. The method of claim 9, further comprising blocking access to the first and second memory regions.

11. The method of claim 8, wherein the determining comprises determining that a memory access error has occurred, in response to the memory access address belonging to the first memory region or the third memory region.

12. The method of claim 8, wherein the determining comprises determining that no memory access error has occurred, in response to the memory access address belonging to the second memory region.

13. The method of claim 12, further comprising unblocking access to the first and second memory regions.

14. The method of claim 8, wherein a size of the first memory region is determined based on a size of pages in the memory, a size of the second memory region, and a main size that is determined based on the size of pages in the memory.

15. A terminal comprising a sub-system for processing a request for access to a memory, the terminal comprising:
an interception module configured to intercept a memory address included in a memory allocation request signal that is sent to the sub-system; and
a determination unit configured to determine a memory access error by comparing the memory address with addresses stored in the memory, and in response to determining that a memory access error has occurred, the determination unit is configured to block access to the memory.

16. The terminal of claim 15, wherein the interception module is further configured to intercept a memory allocation request signal or memory deallocation request signal that is input to an interface of the memory, and configured to allocate a first memory region to detect an overflow and a second memory region to which objects are allocated, each time a memory allocation request signal or memory deallocation request signal is intercepted at the interface of the memory.

17. The terminal of claim 16, wherein the interception module is configured to block access to the first and second memory regions.

18. The terminal of claim 17, wherein the determination unit is configured to compare the memory address to addresses included in the first and second memory regions.

19. The terminal of claim 18, wherein, in response to the determination unit determining that the memory address belongs to the first memory region or to another inaccessible memory region, the interception module is configured to continue to block access to the first and second memory regions.

20. The terminal of claim 18, wherein, in response to the determination unit determining that the memory belongs to the second memory region to which objects are allocated, the interception module is configured to unblock access to the first and second memory regions.
